(19) United States
(12) Patent Application Publication
(10) Pub. No.: US 2025/0210540 A1
(43) Pub. Date: Jun. 26, 2025

(54) SEMICONDUCTOR STRUCTURE WITH STRESS RELIEF LAYER AND THE METHODS FORMING THE SAME

(71) Applicant: Taiwan Semiconductor Manufacturing Co., Ltd., Hsinchu (TW)

(72) Inventors: Ming-Tsu Chung, Hsinchu (TW); Yung-Chi Lin, Su-Lin City (TW); Yan-Zuo Tsai, Hsinchu (TW); Yang-Chih Hsueh, Hsinchu (TW)

(21) Appl. No.: 18/609,870

(22) Filed: Mar. 19, 2024

Related U.S. Application Data
(60) Provisional application No. 63/613,124, filed on Dec. 21, 2023.

(51) Int. Cl. H01L 23/00; H01L 21/56; H01L 23/31; H01L 25/065

(52) U.S. Cl. CPC H01L 23/562; H01L 21/561; H01L 23/3185; H01L 24/08; H01L 24/80; H01L 25/0652; H01L 2224/08145; H01L 2224/80895; H01L 2224/80896

(57) ABSTRACT

A method includes bonding a top die over a bottom wafer, depositing a stress relief layer on the top die and a top surface of the bottom wafer, forming a dielectric gap-filling layer on the stress relief layer, performing a planarization process on the dielectric gap-filling layer, and sawing the dielectric gap-filling layer and the bottom wafer to form a plurality of packages. One of the packages includes the top die, a portion of the stress relief layer, and a bottom die in the bottom wafer.

### PRIORITY CLAIM AND CROSS-REFERENCE

This application claims the benefit of the following provisionally filed U.S. Patent application: Application No. 63/613,124, filed on Dec. 21, 2023, and entitled “SEMICONDUCTOR STRUCTURE WITH STRESS RELIEF LAYER,” which application is hereby incorporated herein by reference.

### BACKGROUND

Integrated circuit packages may have a plurality of package components such as device dies and package substrates bonded together to increase the functionality and integration level. Due to the differences between different materials of the plurality of package components, stress may occur. The stress may cause the warpage of the package components, which in turn causes non-bond issues. Some conductive features that are intended to be bonded to each other are not bonded, resulting in circuit failure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7, 8A, and 9A illustrate views of a process for forming a package including a stress relief layer in accordance with some embodiments.

FIGS. 8B and 9B illustrate the view of the formation of a package with the top dies exposed in accordance with some embodiments.

FIGS. 10 and 11 illustrate a reconstrued wafer and a package sawed from the reconstructed wafer, respectively, in accordance with some embodiments.

FIG. 12 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a stress relief layer and the method of forming the same are provided. In accordance with some embodiments of the present disclosure, a top die is bonded to a bottom die, which may be in a bottom wafer. A stress relief layer is formed on the sidewall of the top wafer and extends on some parts of the top surface of the bottom die. The stress relief layer may have a low Young's modulus and a low density, so that it may relieve some stress applied by an encapsulant (gap-filling material) subsequently formed thereon.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

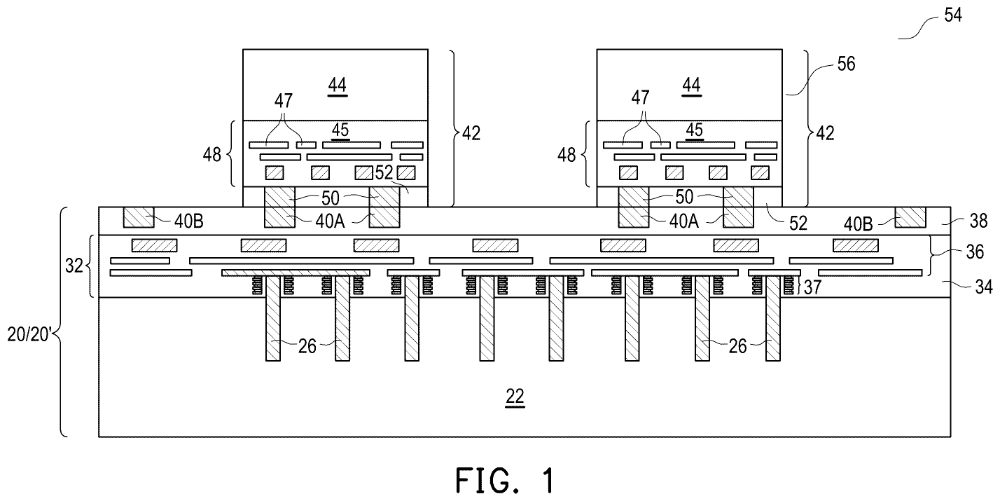

FIGS. 1-7, 8A and 9A illustrate views of a process for forming a package including a stress relief layer in accordance with some embodiments. The corresponding processes are also reflected schematically in the process flow shown in FIG. 12.

FIG. 1 illustrates a cross-sectional view in the formation of package component 20. In accordance with some embodiments, package component 20 is a device wafer, which includes identical device dies 20′ therein. Device dies 20′ may include active devices and possibly passive devices (not shown). In accordance with alternative embodiments, package component 20 is an interposer die, which is free from active devices, and may or may not include passive devices. In accordance with yet alternative embodiments, package component 20 is or comprises a package such as an Integrated Fan-Out (InFO) Package, a redistribution structure including redistribution lines therein, or the like.

In accordance with some embodiments, package component 20 includes semiconductor substrate 22 and the features formed at a top surface of semiconductor substrate 22. Semiconductor substrate 22 may be formed of or comprise crystalline silicon, crystalline germanium, crystalline silicon germanium, carbon-doped silicon, a III-V compound semiconductor, or the like. Semiconductor substrate 22 may also be a bulk semiconductor substrate or a Semiconductor-On-Insulator (SOI) substrate.

In accordance with some embodiments, package component 20 includes integrated circuit devices, which are formed at the top surface of semiconductor substrate. The integrated circuit devices may include Complementary Metal-Oxide Semiconductor (CMOS) transistors, resistors, capacitors, diodes, and/or the like in accordance with some embodiments.

In accordance with some embodiments, package component 20 includes through-vias 26 (also referred to as through-silicon vias (TSVs) 26 or through-semiconductor vias (also TSVs)). TSVs 26 may be electrically connected to the integrated circuit devices. In accordance with some embodiments, TSVs 26 extend from the top surface of semiconductor substrate 22 (or a level higher than the top surface of semiconductor substrate 22) to an intermediate level of semiconductor substrate 22. The intermediate level of semiconductor substrate 22 is between the top surface and the bottom surface of semiconductor substrate 22. Each of the TSVs 26 is encircled by a dielectric isolation layer (not shown), which is used for electrically insulating the corresponding TSV 26 from semiconductor substrate 22.

Interconnect structure 32 is formed over semiconductor substrate 22 and the integrated circuit devices. Interconnect structure 32 may include an Inter-Layer Dielectric (ILD, not marked separately) filling the spaces between the gate stacks of transistors (not shown) in the integrated circuit devices. In accordance with some embodiments, the ILD is formed of silicon oxide, Phospho Silicate Glass (PSG), Boro Silicate Glass (BSG), Boron-doped Phospho Silicate Glass (BPSG), Fluorine-doped Silicate Glass (FSG), or the like. The ILD may be formed using spin-on coating, Flowable Chemical Vapor Deposition (FCVD), or the like. In accordance with some embodiments of the present disclosure, the ILD may also be formed through a deposition process such as Plasma Enhanced Chemical Vapor Deposition (PECVD), Low Pressure Chemical Vapor Deposition (LPCVD), or the like.

Interconnect structure 32 may further include contact plugs (not shown) in the ILD, which contact plugs are used to electrically connect the integrated circuit devices to overlying metal lines and vias. In accordance with some embodiments of the present disclosure, the contact plugs are formed of or comprise a conductive material selected from tungsten, aluminum, copper, titanium, tantalum, titanium nitride, tantalum nitride, alloys therefore, and/or multi-layers thereof. The formation of the contact plugs may include forming contact openings in the ILD, filling a conductive material(s) into the contact openings, and performing a planarization process (such as a Chemical Mechanical Polish (CMP) process or a mechanical grinding process) to level the top surfaces of the contact plugs with the top surface of the ILD.

In accordance with some embodiments, interconnect structure 32 includes a plurality of dielectric layers 34 (which includes the ILD), and a plurality of conductive features such as metal lines/pads 36 and vias 38 in the dielectric layers 34. Dielectric layers 34 may include low-k dielectric layers (also referred to as Inter-metal Dielectrics (IMDs)) in accordance with some embodiments. The dielectric constants (k values) of the low-k dielectric layers may be lower than about 3.5 or 3.0, for example. The low-k dielectric layers may comprise a carbon-containing low-k dielectric material, Hydrogen SilsesQuioxane (HSQ), MethylSilsesQuioxane (MSQ), or the like.

The formation of metal lines and vias 36 in dielectric layers 34 may include single damascene processes and/or dual damascene processes. In a single damascene process for forming a metal line or a via, a trench or a via opening is first formed in one of dielectric layers 34, followed by filling the trench or the via opening with a conductive material. A planarization process such as a CMP process is then performed to remove the excess portions of the conductive material higher than the top surface of the dielectric layer, leaving a metal line or a via in the corresponding trench or via opening.

In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

There may be guard rings 37 encircling each of the TSVs 26, which guard rings 37 are formed in the interconnect structure 32. Interconnect structure 32 may also include a passivation layer (not shown), which is over, and may be in contact with, an underlying top dielectric layer 34. The passivation layer may be formed of a non-low-k dielectric material, which may comprise silicon and another element(s) including oxygen, nitrogen, carbon, and/or the like. For example, the passivation layer may be formed of or comprises SiON, SiN, SiOCN, SiCN, SiOC, SiC, or the like.

Bond layer 38 is formed over redistribution structure 32. Bond layer 38 may be formed of a silicon-containing dielectric material, which silicon-containing dielectric material may be selected from SiO, SiC, SIN, SION, SiOC, SiCN, SiOCN, or the like, or combinations thereof. The bond layer 38 is planarized using a CMP process or a mechanical grinding process so that its top surface is planar.

Bond pads 40 (including bond pads 40A and 40B) are formed in bond layer 38. The active pads 40A in bond pads 40 are electrically connected to the underlying structures including metal lines and vias 36, the integrated circuit devices, and TSVs 26. Bond pads 40 may comprise copper, and may be formed through a damascene process. The bond layer 38 and bond pads 40 are planarized so that their top surfaces are coplanar, which may be resulted due to a CMP process performed in the formation of bond pads 40. In accordance with some embodiments, bond pads 40 include active bond pads 40A and dummy bond pads 40B. The active bond pads 40A are used for bonding to the overlaying top dies, and are electrically connected to the conductive features 36 and possibly TSVs 26. The dummy bond pads 40B may be used for reducing pattern loading effect in the formation, for example, in the CMP process. The dummy bond pads 40B may be electrically floating.

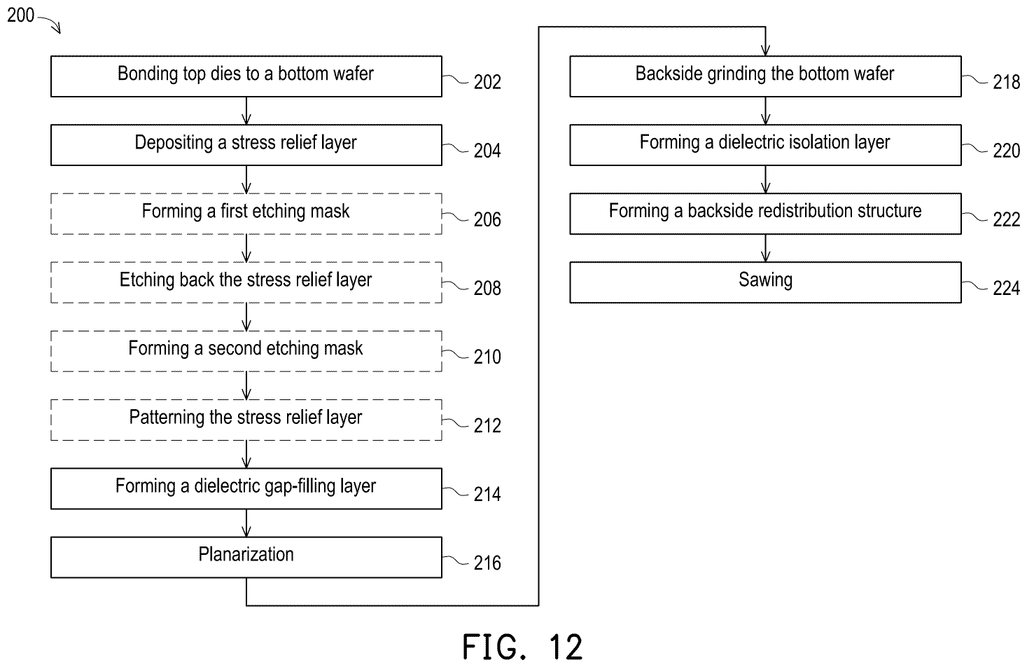

Further referring to FIG. 1, device dies 42 (also referred to as top dies) are bonded to the device dies 20′ (also referred to as bottom dies) in wafer 20. The respective process is illustrated as process 202 in the process flow 200 as shown in FIG. 11. In accordance with some embodiments, each of device dies 42 may be a logic die, which may be a Central Processing Unit (CPU) die, a microcontroller (MCU) die, an input-output (IO) die, a BaseBand die, or the like. Device dies 42 may also include memory dies.

Device dies 42 may include semiconductor substrates 44 and interconnect structures 48 for connecting to the active devices and passive devices in device dies 42. In accordance with some embodiments, each of the interconnect structures 48 includes a plurality of dielectric layers 45, and a plurality of conductive features 47 such as metal lines/pads in the dielectric layers 45. Dielectric layers 45 may include low-k dielectric layers (also referred to as in accordance with some embodiments. The dielectric constants (k values) of the low-k dielectric layers may be lower than about 3.5 or 3.0, for example. The low-k dielectric layers may comprise a carbon-containing low-k dielectric material in accordance with some embodiments.

In accordance with some embodiments, the formation of device dies 42 includes forming a wafer, and then sawing the device dies 42 from the respective wafer. Accordingly, the dielectric layers 45 have their sidewalls exposed. Since dielectric layers 45 may include low-k dielectric layers, which are porous, the low-k dielectric layers are thus prone to absorbing moisture.

Each of device dies 42 includes bond layer 52 (also referred to as a bond film) and bond pads 50 in bond layer 52, wherein the bond layer 52 and bond pads 50 are at the illustrated bottom surface of the respective device die 42. The bottom surfaces of bond pads 50 may be coplanar with the bottom surface of bond layer 52. In accordance with some embodiments, bond layer 52 may be formed of a silicon-containing dielectric material, which may be selected from SiO, SiC, SIN, SION, SiOC, SiCN, SiOCN, or the like, or combinations thereof. Bond pads 50 may comprise copper, and may be formed through a damascene process. The bond layer 52 and bond pads 50 are planarized so that their surfaces are coplanar, which may be resulted due to the CMP in the formation of bond pads 50.

The bonding may be achieved through hybrid bonding. For example, bond pads 50 are bonded to bond pads 40A through metal-to-metal direct bonding. In accordance with some embodiments, the metal-to-metal direct bonding includes copper-to-copper direct bonding. Furthermore, bond layers 52 are bonded to bond layer 38 through fusion bonding, for example, with Si—O—Si bonds being generated. The structure illustrated in FIG. 1 is referred to as reconstructed wafer 54 hereinafter, and more features are formed in subsequent processes to further expand the reconstructed wafer 54.

In accordance with some embodiments, a backside grinding process may be performed to thin the semiconductor substrates 44 of device dies 42. Through the thinning of semiconductor substrates 44, the aspect ratio of the gaps between neighboring device dies 42 is reduced in order to perform gap filling. Otherwise, the subsequent gap filling process may be difficult due to the otherwise high aspect ratio of the gaps.

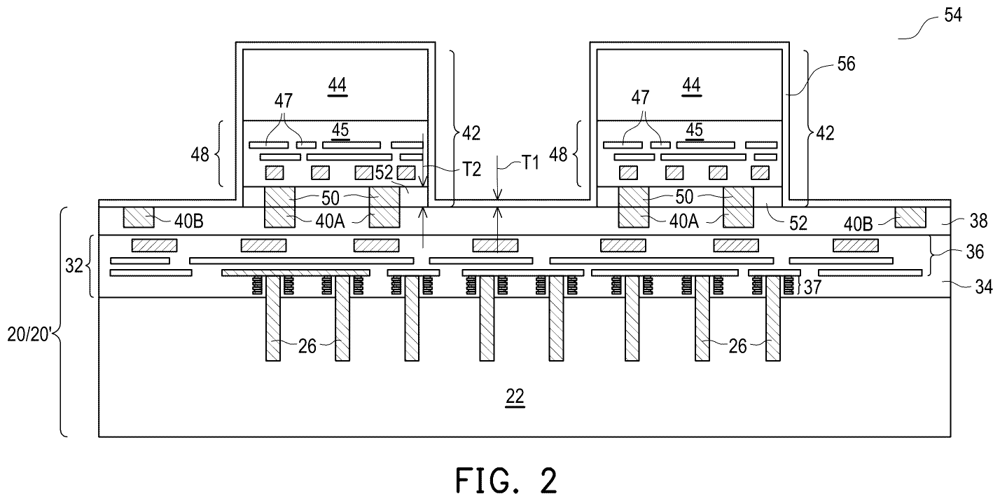

Referring to FIG. 2, stress relief layer 56 is formed by depositing or coating process. The respective process is illustrated as process 204 in the process flow 200 as shown in FIG. 12. In accordance with some embodiments, stress relief layer 56 is deposited using Chemical Vapor Deposition (CVD). Alternatively, other deposition methods that may form conformal layers or close-to conformal layers such as low-pressure CVD (LPCVD), plasma enhanced CVD (PECVD), Atomic Layer Deposition (ALD), or the like, may also be used.

In accordance with some embodiments, stress relief layer 56 comprises a silicon-containing dielectric material such as silicon nitride, silicon oxide, silicon carbonitride, silicon oxynitride, silicon oxy carbonitride, silicon carbide, or the like. In accordance with alternative embodiments, stress relief layer 56 comprises a metal-containing dielectric material such as a metal oxide, a metal nitride, a metal oxynitride, or the like. For example, stress relief layer 56 may comprise TiO, TIN, TION, or the like.

In accordance with some embodiments, the process conditions for depositing stress relief layer 56 is adjusted, so that stress relief layer 56 has reduced internal (inherent) stress and reduced density. For example, the internal stress of stress relief layer 56 may be smaller than about 30 MPa in accordance with some embodiments. The density of stress relief layer 56 may be lower than about 2.2 grams/cm³, or lower than about 2.0 grams/cm³, and may be in the range between about 1.8 grams/cm³ and about 2.0 grams/cm³.

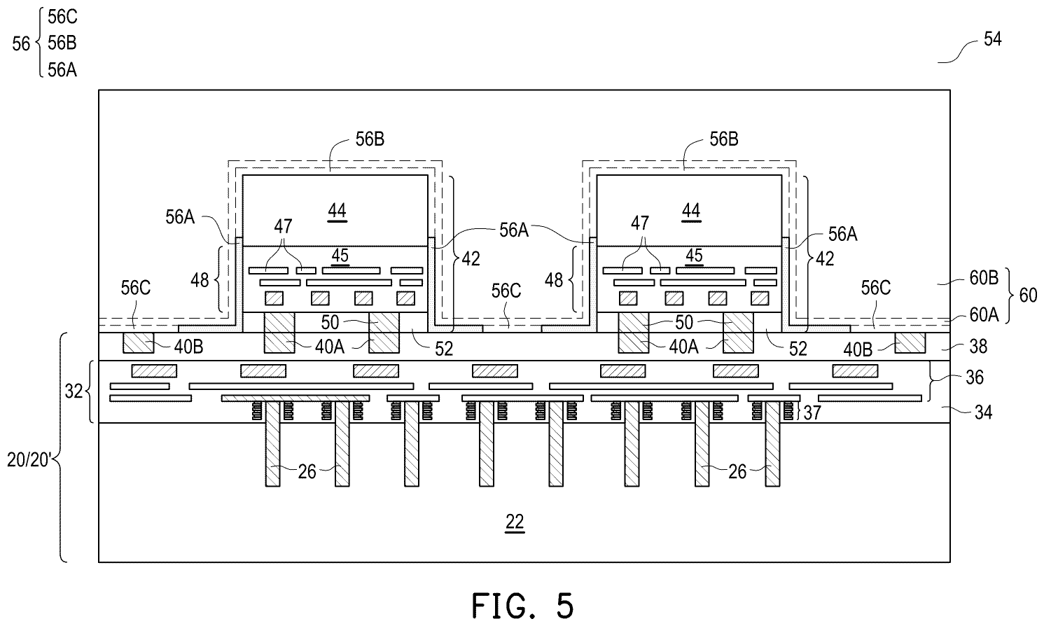

Also, stress relief layer 56 may have reduced Young's modulus, for example, comparing to adhesion layer 60A when adhesion layer (liner) 60A (FIG. 5) is formed, and comparing to gap-filling regions 60 when the gap-filling regions 60 are formed of molding compound. Reducing both of the density and the Young's modulus of stress relief layer 56 helps the stress relief layer 56 to absorb stress, and to buffer the stress passed from the overlying gap-filling regions 60.

Reducing the density and the Young's modulus of stress relief layer 56 may be achieved by adjusting the process conditions for depositing stress relief layer 56. In accordance with some embodiments, the reduction of the density of the Young's modulus of stress relief layer 56 may be achieved by increasing the deposition rate of stress relief layer 56. For example, when CVD is used, the reduction of the density of the Young's modulus of stress relief layer 56 may be achieved by reducing the source power and/or bias power. In accordance with some embodiments, the source power is smaller than about 800 watts, and may be in the range between about 500 watts and about 1,200 watts. The bias power may be smaller than about 1,600 watts, and may be in the range between about 1,200 watts and about 2,400 watts.

In accordance with alternative embodiments, reducing the density and the Young's modulus of stress relief layer 56 may be achieved by increasing the gas flow rate of the precursors of stress relief layer 56. For example, when CVD is used, and when stress relief layer 56 comprises silicon and nitrogen, the reduction of the density and the Young's modulus of stress relief layer 56 may be achieved by increasing the gas flow of precursors such as Tetraethyl orthosilicate (TEOS) and 02. In accordance with some embodiments, the flow rate of 02 may be greater than about 22,500 sccm, and may be in the range between about 15,000 sccm and about 30,000 sccm. The flow rate of TEOS may be greater than about 5.5 sccm, and may be in the range between about 4 sccm and about 6 sccm.

In accordance with some embodiments, the thickness of the stress relief layer 56 is selected to be in certain range to maximize the effect of relieving stress. When stress relief layer 56 is too thin, the effect of relieving stress is too small. When the stress relief layer 56 is too thick, it occupies too much volume of the gap-filling region. In accordance with some embodiments, the stress relief layer 56 has thickness T1 smaller than about 10 μm and greater than about 0.5 μm. The thickness ratio T1/T2 may be smaller than about 15, wherein thickness T2 is the thickness of bond layer 52.

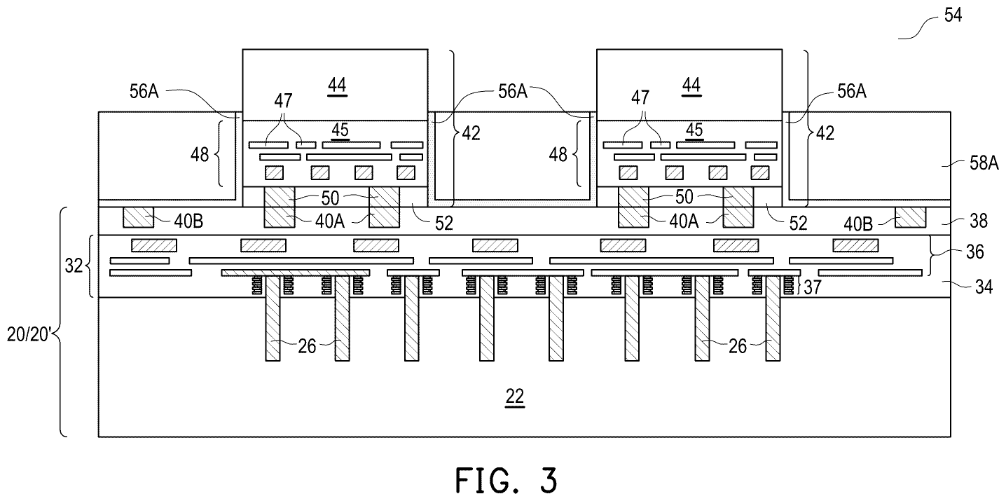

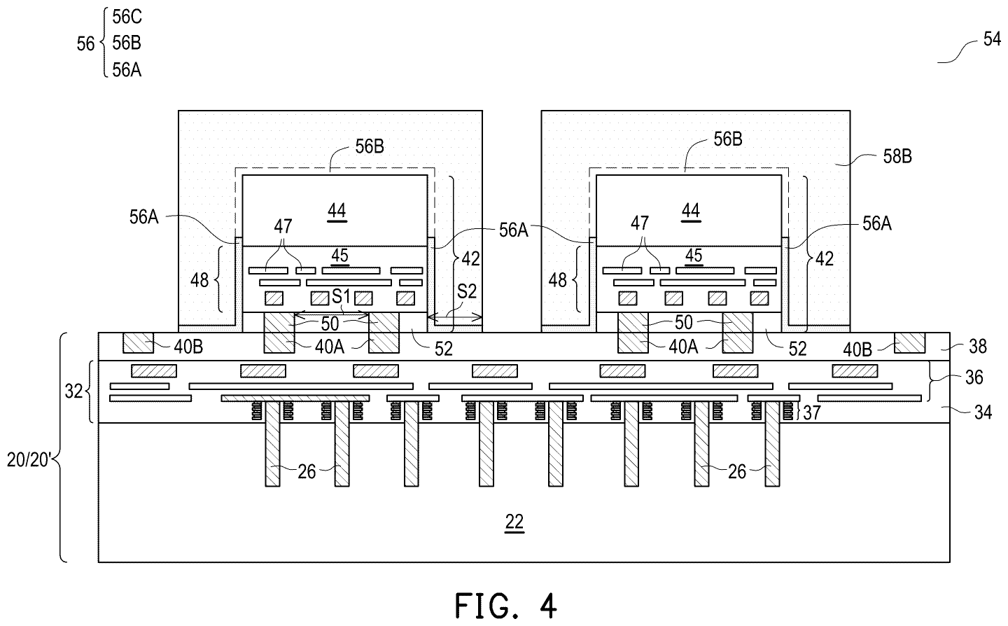

Stress relief layer 56 has a higher density than the low-k dielectric layers (parts of dielectric layers 45) in interconnect structure 48. Accordingly, stress relief layer 56, in addition to the function of relieving stress, also has the function of blocking moisture from reaching from the external environment to the low-k dielectric layers in interconnect structure 48. As will be discussed referring to subsequent figures, stress relief layer 56 may be un-patterned, and remain as a blanket layer in the final package. In accordance with alternative embodiments, stress relief layer 56 is patterned, as discussed referring to FIGS. 3 and 4. Regardless of being patterned or un-patterned, in the final package, stress relief layer 56 is formed on, and protects, all of the sidewalls of the low-k dielectric layers in interconnect structure 48.

FIG. 3 illustrates the patterning of stress relief layer 56 in accordance with some embodiments. In accordance with these patterning processes, an etching mask 58A may be formed. The respective process is illustrated as process 206 in the process flow 200 as shown in FIG. 12. In accordance with some embodiments, etching mask 58A comprises photoresist or another organic or in organic material. When etching mask 58A comprises photoresist or another organic material, etching mask 58A may be formed by spin-on coating, and is cured. When etching mask 58A comprises an inorganic material (e.g., silicon nitride), etching mask 58A may be a hard mask formed through a deposition process, following by a planarization process such as a CMP process or a mechanical grinding process.

A process is then performed to reduce the top surface of etching mask 58A to be lower than the top surface of semiconductors 44. The process may be an etch-back process. The semiconductor substrates 44 of top dies 42 are revealed. The respective process is illustrated as process 208 in the process flow 200 as shown in FIG. 12. In accordance with some embodiments, the top surface of etching mask 58A is higher than the illustrated bottom surfaces of semiconductor substrates 44. This ensures that in the subsequent patterning of stress relief layer 56, the remaining portions of the stress relief layer 56 have top ends higher than the illustrated top surface of interconnect structures 48, so that the sidewalls of the low-k dielectric layers in the interconnect structures 48 are protected. The illustrated top surfaces of interconnect structures 48 also form interfaces with the respective overlying semiconductor substrates 44. In accordance with some embodiments, the top ends of the stress relief layer 56 are lower than the middle point between the top surfaces and the corresponding bottom surfaces of the semiconductor substrates 44.

In a subsequent process, an etching process is performed to remove the exposed portions of the stress relief layer 56 that are not protected by etching mask 58A. The etching process may be an isotropic etching process, which may be a dry etching process. The portions of the stress relief layer 56 on top of the top dies 42 and the upper portions of the sidewalls of semiconductor substrates 44 are removed. The lower portions of the stress relief layer 56 on the top surface of wafer 20 and the sidewalls of dielectric layers 45 remain un-etched. In a subsequent process, the etching mask 58A is removed.

FIG. 4 illustrates the patterning of stress relief layer 56 in accordance with alternative embodiments. In accordance with these patterning process, an etching mask 58B is formed. The respective process is illustrated as process 210 in the process flow 200 as shown in FIG. 12. In accordance with some embodiments, etching mask 58B comprises a photoresist, which is patterned in a lithography process. The remaining portions of etching mask 58B may fully protect top dies 42, while leaving some portions of stress relief layer 56 on the top surface of wafer 20 exposed.

Also, the remaining portions of etching mask 58B may extend beyond the edges of the top dies 42 by distance S2 that is greater than the spacings of neighboring bond pads 50. By keeping distance S2 to be large enough, the stress relief layer 56's ability of relieving stress is not sacrificed. In accordance with some embodiments, spacing S1 is smaller than about 9 μm, and thus spacing S2 is greater than about 10 μm.

In a subsequent process, an etching process is performed to remove the exposed portions of the stress relief layer 56 not protected by etching mask 58B. The respective process is illustrated as process 212 in the process flow 200 as shown in FIG. 12. The etching process may be an isotropic etching process, which may be a dry etching process or a wet etching process. In the resulting structure, some portions of the stress relief layer 56 are left un-etched, while portions of the stress relief layer 56 away from top dies 42 are removed. The remaining portions the stress relief layer 56 may form rings encircling (and contacting) top dies 42. In a subsequent process, the etching mask 58B is removed.

In accordance with some embodiments, the etching process as shown in FIG. 3 is performed, while the etching process as shown in FIG. 4 is not performed. Accordingly, the portions 56A of stress relief layer 56 remains to be in the final package, while the portions 56B (FIG. 5) are removed. In accordance with alternatively embodiments, the etching process as shown in FIG. 4 is performed, while the etching process as shown in FIG. 3 is not performed. Accordingly, the portions 56A of stress relief layer 56 remains to be in the final package, while the portions 56C (FIG. 5) are removed.

In accordance with yet embodiments, both of the etching process as shown in FIG. 3 and the etching process as shown in FIG. 4 are performed. Accordingly, the portions 56A of stress relief layer 56 remains to be in the final package, while the portions 56B and 56C (FIG. 5) are removed. When both of the patterning processes as shown in FIGS. 3 and 4 are performed, the top portions 56B may be removed before the portions 56C. Alternatively, the order as shown in FIGS. 3 and 4 may be inversed, and portions 56C may be removed before the removal of portions 56B. In subsequent figures, portions 56B and 56C are illustrated as being dashed to indicate that these portions may be removed or may remain in accordance with various embodiments.

In accordance with some embodiments, after the processes shown in FIG. 4 (if any) is performed, the remaining portions 56A covers dummy metal pad 40B. Alternatively, after the patterning process as shown in FIG. 4, dummy metal pad 40B are exposed.

FIG. 5 illustrates the formation of the dielectric gap-filling layer(s) 60 over and contacting stress relief layer 56. The respective process is illustrated as process 214 in the process flow 200 as shown in FIG. 12. In accordance with some embodiments, an entire dielectric gap-filling layer 60 comprises a molding compound, which may comprise a base material and filler particles in the base material. The base material may comprise a polymer, a resin, and/or an epoxy. The filler particles may comprise silica, aluminum oxide, silicon oxide and the like. The formation process may include dispensing the molding compound in a flowable form, and curing the molding compound as a solid.

In accordance with alternative embodiments, dielectric gap-filling layer 60 may include a dielectric liner 60A and a dielectric layer 60B over dielectric liner 60A, wherein dielectric liner 60A and dielectric layer 60B are formed of different materials. For example, dielectric liner 60A may comprise a nitride (such as silicon nitride, silicon oxynitride, or the like), and dielectric layer 60B may comprise an oxide (such as silicon oxide).

In accordance with these embodiments, dielectric liner 60A and stress relief layer 56 may be formed of the same dielectric material (such as silicon nitride or silicon oxynitride) or different materials, while dielectric liner 60A still has a higher density and higher Young's modulus (and a higher dielectric constant) than stress relief layer 56. This may be achieved by adjusting process conditions. For example, the source voltage and/or bias voltage for depositing stress relief layer 56 may be adjusted to be lower than the corresponding the source voltage and/or bias voltage for depositing dielectric liner 60A. The flow rate of the precursors for depositing dielectric liner 60A may also be adjusted to be higher than the flow rates of the corresponding precursors for depositing stress relief layer 56. This may cause stress relief layer 56 to have a higher deposition rate than dielectric liner 60A when they are formed of the same material.

For example, stress relief layer 56 and dielectric liner 60A may be formed of the same material (such as silicon nitride or silicon oxynitride), and may have the same composition or different compositions. Throughout the description, when two materials have same elements and the percentages of the elements are also the same, the two materials are referred to as having the same composition. Otherwise, if two materials have different elements and/or different percentages of the elements, the two materials are referred to as having different compositions. Stress relief layer 56 and dielectric liner 60A may have the same compositions or different compositions. Furthermore, stress relief layer 56 and dielectric liner 60A may include the same elements but still have different compositions, or may include different elements.

By reducing the flow rates of the precursors (which may be the same precursors as that for forming stress relief layer 56) for forming dielectric liner 60A, the density and the Young's modulus of dielectric liner 60A may be higher than that of stress relief layer 56, regardless of whether dielectric liner 60A and stress relief layer 56 have the same or different compositions.

In accordance with some embodiments, when dielectric liner 60A is not formed, the entire dielectric gap-filling layer 60 may be formed of a homogenous material such as silicon oxide, silicon carbide, silicon oxynitride, silicon oxy-carbo-nitride, or the like. Dielectric gap-filling layer 60 may have a higher density DS60 and a higher Young's modulus YM60 than the density DS56 and the Young's modulus YM56 of stress relief layer 56. In accordance with these embodiments, the density ratio DS60/D56 is greater than about 1.05 or greater than about 1.1, and the Young's modulus ratio YM60/YM56 may also be greater than about 1.05 or greater than about 1.1. Conversely, when dielectric liner 60A is formed, the corresponding density ratio DS60A/D56 and the Young's modulus ratio YM60A/YM56 may fall into similar ranges, wherein values DS60A and YM60 are the density and the Young's modulus, respectively, of dielectric liner 60A.

In accordance with some embodiments, when the process as shown FIG. 3 has been performed, dielectric gap-filling layer 60 is in physical contact with the upper parts of the sidewalls of semiconductor substrates 44. When the process as shown FIG. 4 has been performed, dielectric gap-filling layer 60 is in physical contact with the top surface of wafer 20, and may or may not be in physical contact with dummy bond pads 40B. Otherwise, dielectric gap-filling layer 60 will be separated from semiconductor substrates 44 and/or from the top surface of wafer 20, depending on which of the processes shown in FIGS. 3 and 4 are not performed.

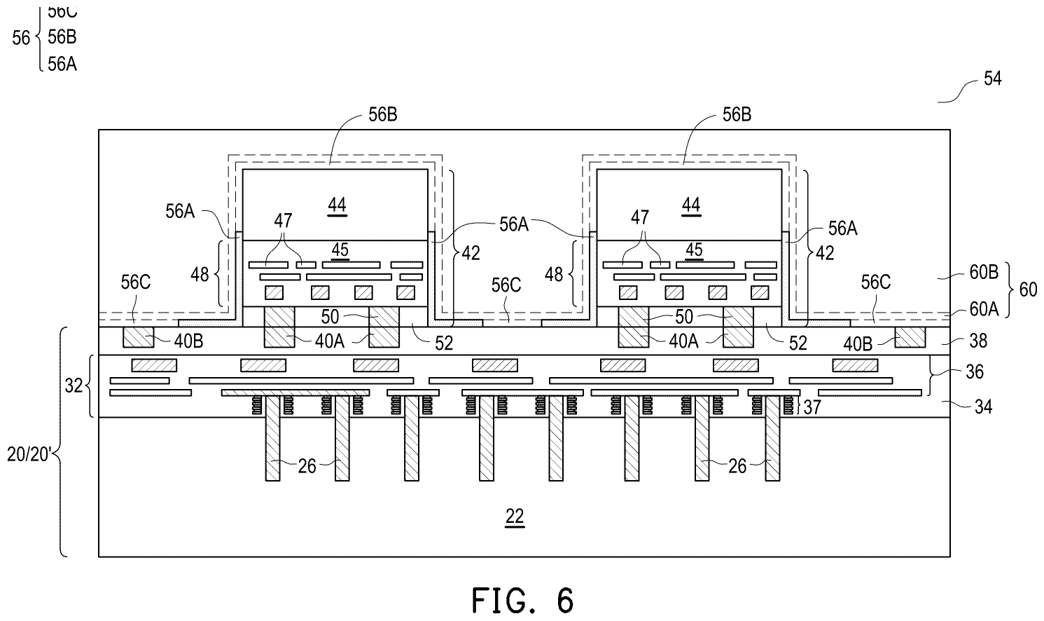

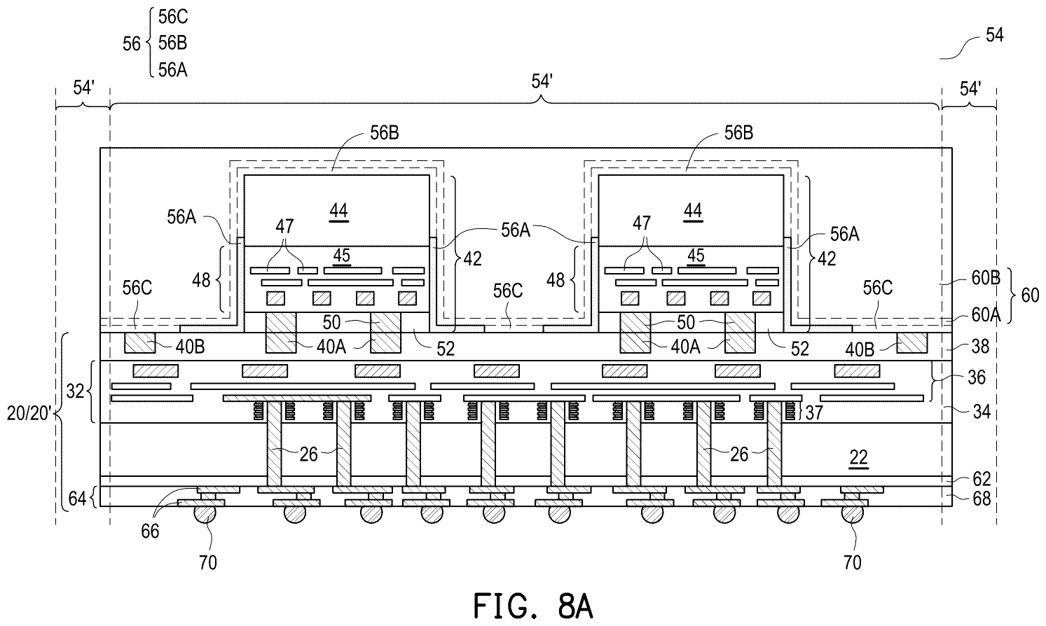

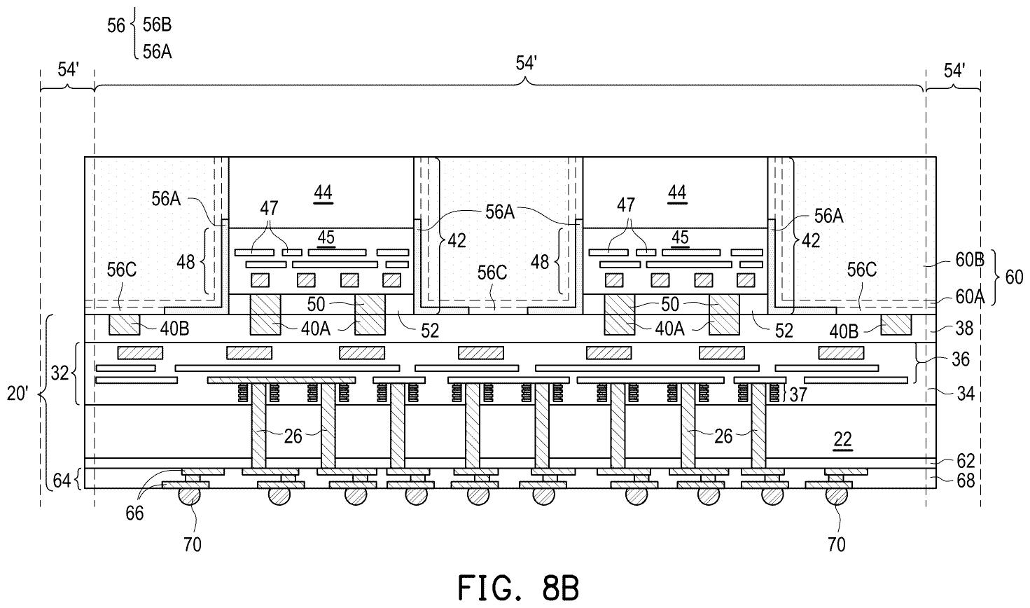

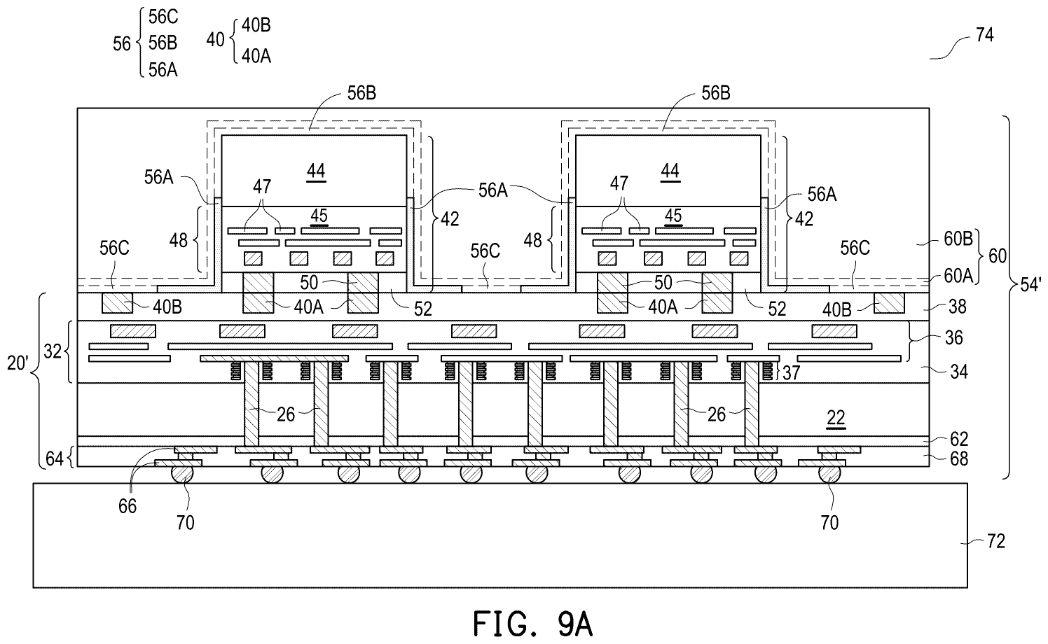

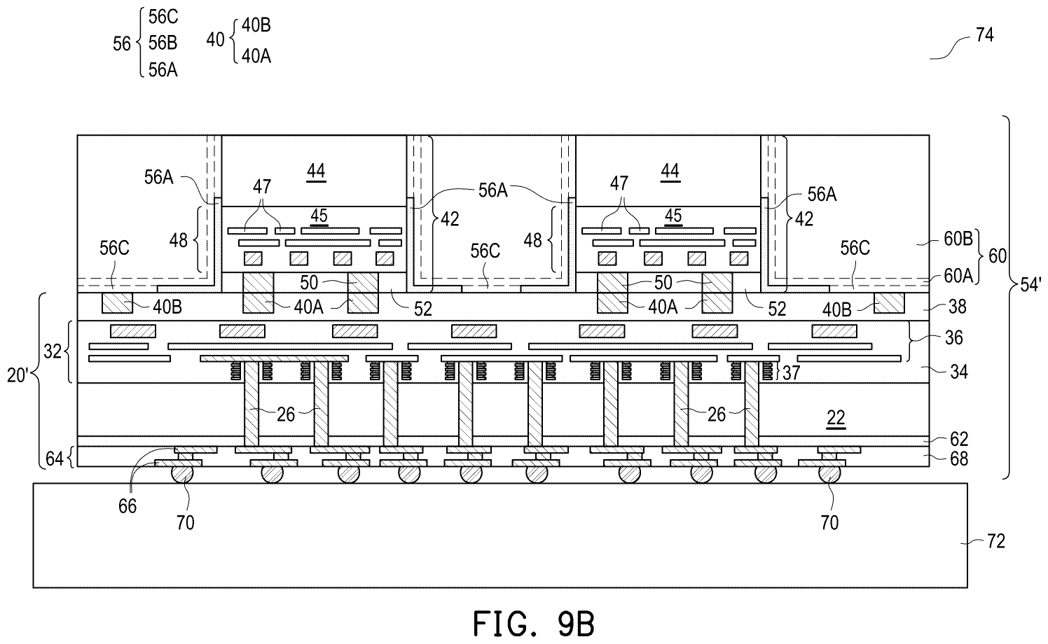

Referring to FIG. 6, a planarization process such as a CMP process or a mechanical grinding process is performed to thin dielectric gap-filling layer 60. The respective process is illustrated as process 216 in the process flow 200 as shown in FIG. 12. In accordance with some embodiments, after the planarization process, a portion dielectric gap-filling layer 60 remains to overlap top dies 42. In accordance with alternative embodiments, the planarization process is performed until the semiconductor substrates 44 are exposed. The corresponding structure is shown in FIGS. 8B and 9B.

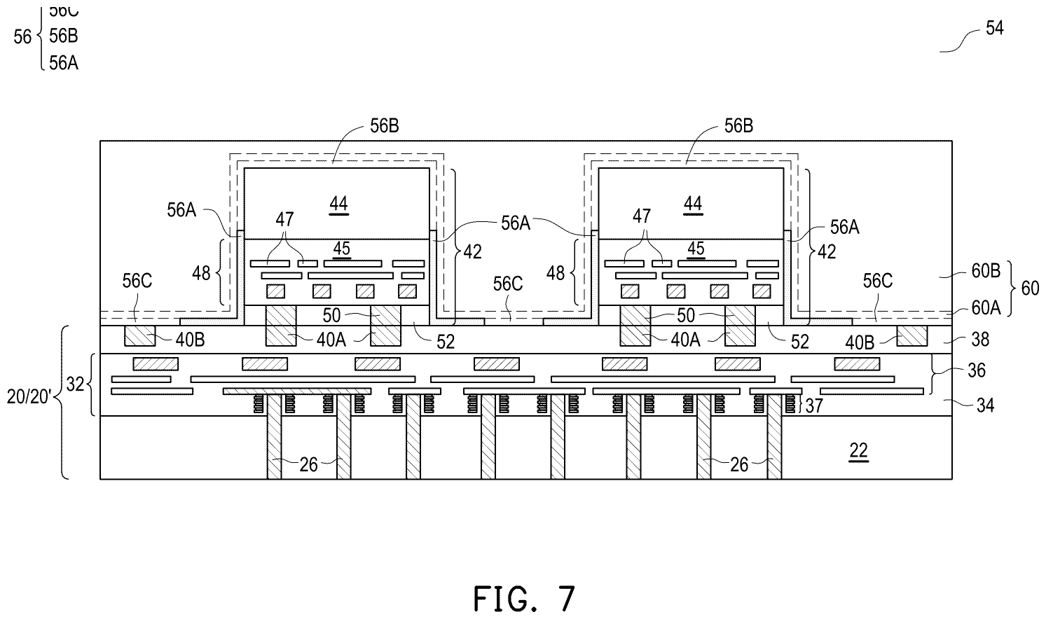

FIG. 7 illustrates the backside grinding process for thinning semiconductor substrate 22 from backside. The respective process is illustrated as process 218 in the process flow 200 as shown in FIG. 12. In accordance with some embodiments, the backside grinding process is performed through CMP process or a mechanical grinding process. As a result of the backside grinding process, TSVs 26 are revealed.

Next, the semiconductor substrate 22 in device dies 20′ may be recessed to form recesses, and some portions (the illustrated bottom portions) of TSVs 26 protrude beyond semiconductor substrate 22. Dielectric isolation layer 62 may then be formed, as shown in FIG. 8. The respective process is illustrated as process 220 in the process flow 200 as shown in FIG. 12. The formation of dielectric isolation layer 62 may include a deposition process to deposit a dielectric layer into the recesses generated by recessing semiconductor substrate 22, so that the protruding portions of TSVs 26 are in the dielectric layer, followed by a planarization process. The portions of the dielectric layer beyond TSVs 26 are removed, and the remaining portions of the dielectric layer form the dielectric isolation layer 62, which becomes parts of device dies 20′ and wafer 20.

FIG. 8A illustrates the formation of backside redistribution structure 64, which includes dielectric layers 68 and RDLs 66 in dielectric layers 68. The respective process is illustrated as process 222 in the process flow 200 as shown in FIG. 12. The backside redistribution structure 64 may be formed layer-by-layer. For example, the formation of one layer of RDLs 66 may include forming a dielectric layer 68, and forming openings in the dielectric layer 68 through a patterning process. Dielectric layers 68 may be formed of or comprise an organic material such as PBO, polyimide, BCB, or the like, or an inorganic material such as silicon oxide, silicon nitride, or the like.

A metal seed layer (not shown) is then deposited, which includes some portions outside of, and some other portions extending into, dielectric layer 68. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed, leaving a layer of RDLs 66.

FIG. 8A further illustrates the formation of electrical connectors 70 on reconstructed wafer 54. In accordance with some embodiments, electrical connectors 70 include solder regions, metal pillars, solder layers, and/or the like. The reconstructed wafer 54 may then be sawed to form packages 54′. The respective process is illustrated as process 224 in the process flow 200 as shown in FIG. 12.

In a subsequent process, as shown in FIG. 9A, package 54′ is bonded to package component 72. In accordance with some embodiments, package component 72 comprises a package substrate, an interposer, another package, a printed circuit board, or the like. Package 74 is thus formed.

FIGS. 8B and 9B illustrate the formation of package 74 in accordance with alternative embodiments. These embodiments are similar to the embodiments as shown in FIGS. 8A and 9A, except that the preceding planarization process of dielectric gap-filling layer 60 is performed until the semiconductor substrates 44 of top dies 42 have been exposed.

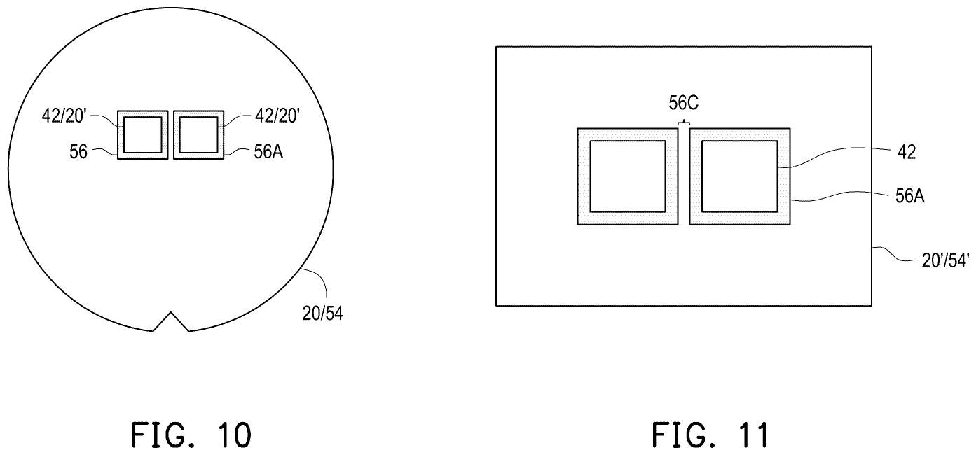

FIG. 10 illustrates the top view of the reconstructed wafer 54 before the sawing process. Two top dies 42 are illustrated as an example group, while the actual reconstructed wafer 54 may include a plurality of groups of top dies 42, which groups may form an array. In accordance with some embodiment, stress relief layer 56 is a blanket layer covering the entire wafer 20, and extends to all edges of the reconstructed wafer 54. In accordance with alternative embodiments, as shown in FIG. 10, stress relief layer 56 is patterned as a plurality of portions 56A, each on one of top dies 42, and also includes a ring portion extending outwardly from the corresponding top die 42.

FIG. 11 illustrates a top view of one of the packages 54′ sawed from the reconstructed wafer 54 in accordance with some embodiments. In accordance with some embodiment, stress relief layer 56 is a blanket layer covering the entire die 20′ and top dies 42, and extends to all edges of the package 54′. In accordance with alternative embodiments, stress relief layer 56 is patterned, and the portions 56A of stress relief layer 56 extending out from different ones of top dies 42 may be separated from each other, or may have a connecting portion 56C joining them to each other.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming the stress relief layer, which has the function of relieving stress, the stress applied by the subsequently formed gap-filling layer (encapsulant) is relieved. The stress relief layer also helps to block moisture from reach the low-k dielectric layers in the top dies.

In accordance with some embodiments of the present disclosure, a method comprises bonding a top die over a bottom wafer; depositing a stress relief layer on the top die and a top surface of the bottom wafer; forming a dielectric gap-filling layer on the stress relief layer; performing a planarization process on the dielectric gap-filling layer; and sawing the dielectric gap-filling layer and the bottom wafer to form a plurality of packages, wherein one of the packages comprises the top die, a portion of the stress relief layer, and a bottom die in the bottom wafer.

In an embodiment, the method further comprises forming an etching mask on the stress relief layer; recessing the etching mask until a first top surface of the etching mask is lower than a second top surface of the top die; performing an etching process to remove portions of the stress relief layer higher than the first top surface; and removing the etching mask. In an embodiment, one of the portions of the stress relief layer removed in the etching process is on the second top surface of the top die. In an embodiment, the method further comprises forming a patterned etching mask on the stress relief layer; performing an etching process to remove portions of the stress relief layer; and removing the patterned etching mask.

In an embodiment, one of the portions of the stress relief layer removed in the etching process is on a top surface of the bottom die. In an embodiment, the dielectric gap-filling layer comprises a molding compound, and the molding compound is in physical contact with the stress relief layer. In an embodiment, the dielectric gap-filling layer comprises a dielectric liner; and a dielectric layer over the dielectric liner. In an embodiment, the stress relief layer and the dielectric liner are formed of a same material, and the stress relief layer is formed with a higher deposition rate than the dielectric liner. In an embodiment, the stress relief layer and the dielectric liner are formed of a same material, and the stress relief layer has a lower density than the dielectric liner.

In accordance with some embodiments of the present disclosure, a structure comprises a bottom die; a top die over and joined to the bottom die; a stress relief layer comprising a first portion contacting a sidewall of the top die; and a dielectric gap-filling region on the stress relief layer, wherein the stress relief layer is further in physical contact with a top surface of the bottom die. In an embodiment, the dielectric gap-filling region comprises a molding compound in physical contact with the stress relief layer. In an embodiment, the dielectric gap-filling region comprises a dielectric liner; and a dielectric layer over and contacting the dielectric liner, wherein the dielectric liner comprises a different material than the dielectric layer.

In an embodiment, the dielectric liner and the stress relief layer comprise a same material, and the stress relief layer has a lower density than the dielectric liner. In an embodiment, the top die comprises a semiconductor substrate and an interconnect structure under the semiconductor substrate, and wherein the stress relief layer has a top end higher than an interface between the semiconductor substrate and the interconnect structure, and the top end is lower than an additional top surface of the top die. In an embodiment, in a top view of the structure, the second portion forms a ring encircling the first portion.

In accordance with some embodiments of the present disclosure, a structure comprises a bottom die; a top die over and joined to the bottom die, wherein the top die comprises a semiconductor substrate; and an interconnect structure under the semiconductor substrate; a stress relief layer comprising a first portion contacting a first sidewall of the interconnect structure, wherein a top end of the stress relief layer is higher than an interface between the semiconductor substrate and the interconnect structure, and wherein the top end of the stress relief layer is lower than a top surface of the semiconductor substrate; and a dielectric gap-filling region on the stress relief layer.

In an embodiment, the dielectric gap-filling region is further in physical contact with a second sidewall of the semiconductor substrate. In an embodiment, the dielectric gap-filling region is further in physical contact with an additional top surface of the bottom die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a top die over a bottom wafer;
depositing a stress relief layer on the top die and a top surface of the bottom wafer;
forming a dielectric gap-filling layer on the stress relief layer;
performing a planarization process on the dielectric gap-filling layer; and
sawing the dielectric gap-filling layer and the bottom wafer to form a plurality of packages, wherein one of the packages comprises the top die, a portion of the stress relief layer, and a bottom die in the bottom wafer.

2. The method of claim 1 further comprising:
forming an etching mask on the stress relief layer;
recessing the etching mask until a first top surface of the etching mask is lower than a second top surface of the top die;
performing an etching process to remove portions of the stress relief layer higher than the first top surface; and
removing the etching mask.

3. The method of claim 2, wherein one of the portions of the stress relief layer removed in the etching process is on the second top surface of the top die.

4. The method of claim 1 further comprising:
forming a patterned etching mask on the stress relief layer;
performing an etching process to remove portions of the stress relief layer; and
removing the patterned etching mask.

5. The method of claim 4, wherein one of the portions of the stress relief layer removed in the etching process is on a top surface of the bottom die.

6. The method of claim 1, wherein the stress relief layer comprises a metal-containing dielectric material.

7. The method of claim 1, wherein the dielectric gap-filling layer comprises a molding compound, and the molding compound is in physical contact with the stress relief layer.

8. The method of claim 1, wherein the dielectric gap-filling layer comprises:
a dielectric liner; and
a dielectric layer over the dielectric liner.

9. The method of claim 8, wherein the stress relief layer and the dielectric liner are formed of a same material, and the stress relief layer is formed with a higher deposition rate than the dielectric liner.

10. The method of claim 8, wherein the stress relief layer and the dielectric liner are formed of a same material, and the stress relief layer has a lower density than the dielectric liner.

11. A structure comprising:
a bottom die;
a top die over and joined to the bottom die;
a stress relief layer comprising a first portion contacting a sidewall of the top die and a second portion contacting a top surface of the bottom die; and
a dielectric gap-filling region on the stress relief layer.

12. The structure of claim 11, wherein the stress relief layer further comprises a third portion contacting a top surface of the top die.

13. The structure of claim 11, wherein the dielectric gap-filling region comprises a molding compound in contact with the stress relief layer.

14. The structure of claim 11, wherein the dielectric gap-filling region comprises:
a dielectric liner; and
a dielectric layer over and contacting the dielectric liner, wherein the dielectric liner comprises a different material than the dielectric layer.

15. The structure of claim 14, wherein the dielectric liner and the stress relief layer comprise a same material, and the stress relief layer has a lower density than the dielectric liner.

16. The structure of claim 11, wherein the top die comprises a semiconductor substrate and an interconnect structure under the semiconductor substrate, and wherein the stress relief layer has a top end higher than an interface between the semiconductor substrate and the interconnect structure, and the top end is lower than an additional top surface of the top die.

17. The structure of claim 11, wherein in a top view of the structure, the second portion forms a ring encircling the first portion.

18. A structure comprising:
a bottom die;
a top die over and joined to the bottom die, wherein the top die comprises:
a semiconductor substrate; and
an interconnect structure under the semiconductor substrate;
a stress relief layer comprising a first portion contacting a first sidewall of the interconnect structure, wherein a top end of the stress relief layer is higher than an interface between the semiconductor substrate and the interconnect structure, and wherein the top end of the stress relief layer is lower than a top surface of the semiconductor substrate; and
a dielectric gap-filling region on the stress relief layer.

19. The structure of claim 18, wherein the dielectric gap-filling region is further in physical contact with a second sidewall of the semiconductor substrate.

20. The structure of claim 18, wherein the dielectric gap-filling region is further in physical contact with an additional top surface of the bottom die.
